(19) United States
(12) Patent Application Publication
(10) Pub. No.: US 2022/0206750 A1
(43) Pub. Date: Jun. 30, 2022

(54) PROGRAMMABLE ANALOG SIGNAL PROCESSING ARRAY FOR TIME-DISCRETE PROCESSING OF ANALOG SIGNALS

(71) Applicant: IHP GmbH - Innovations for High Performance Microelectronics / Leibniz-Institut fur Innovative Mikro, Frankfurt (Oder) (DE)

(72) Inventors: Gerhard KAHMEN, Frankfurt (Oder) (DE); Eckhard GRASS, Frankfurt (Oder) (DE)

(21) Appl. No.: 17/563,493

(22) Filed: Dec. 28, 2021

(30) Foreign Application Priority Data
Dec. 30, 2020 (EP) 20217781.2
May 27, 2021 (EP) 21176328.9

(51) Int. Cl. G06F 7/523; H03K 5/135

(52) U.S. Cl. CPC G06F 7/523; G11C 13/0002; H03K 5/135

(57) ABSTRACT

A programmable analog processing array for programmable time-discrete processing of analog input signals in accordance with a desired signal processing function comprises a network of mutually interconnectable and pre-configurable analog processing slices that form unit circuit cells of the network. Each processing slice comprises a set of cell circuit elements including: a switchable clock input port for receiving a clock signal, a delay element for receiving a respective analog slice input signal and for forwarding the received slice input signal with a pre-configurable time delay as a respective delayed slice input signal, an analog multiplier element receiving the delayed slice input signal for providing an analog multiplier output signal corresponding to a product of the delayed slice input signal with a pre-configurable multiplication factor, an analog adder element receiving a pre-configurable selection of at least two adder input signals including the multiplier output signal and for providing an analog adder output signal corresponding to a sum of the adder input signals, and including an analog resample element for receiving the adder output signal and for providing the received adder output with a pre-configurable time delay as an analog slice output signal.

### FIELD OF THE INVENTION

The present invention is in the field of signal processing of analog signals. It relates to a programmable analog signal processing array for processing incoming analog input voltage signals in accordance with a programmable signal processing function and for providing processed analog output voltage signals.

### BACKGROUND OF THE INVENTION

One typical application area of programmable analog signal processing arrays are analog signal processing units operated as Finite-Impulse Response (FIR) filter, Infinite-Impulse-Response (IIR) filter, and rank filter.

US 2010/0033228 A1 describes logic automata in the context of a reconfigurable statistical signal processing apparatus that comprises an array of discrete-time analog signal processing circuitry for statistical signal processing, based on a local message-passing algorithm and digital configuration circuitry for controlling the functional behavior of the array of analog circuitry. The signal processing apparatus serves for applications such as coding, decoding, and image processing, and employs features of analog logic in the context of a cellular automata architecture. Analog Logic Automata hardware provides a continuous-state, discrete-time computation model for modeling and solving digital signal processing problems by implementing local message-passing algorithms in a programmable fashion. The input signal to the apparatus is expressed as a probabilistic representation. The analog circuitry comprises computational elements arranged in a network, with a receiving module that assigns probability values when an input signal arrives and communicates the probability values to one of the computational elements, the computational elements producing outputs based on the assigned probability values. The signal processing apparatus of US 2010/0033228 A1 thus forms an array of analog logic automata cells, wherein each cell is able to communicate with all neighboring cells.

### SUMMARY OF THE INVENTION

According to the present invention, a programmable analog signal processing array for programmable time-discrete processing of incoming analog input signals in accordance with a desired signal processing function and for providing processed analog output signals in accordance with the signal processing function is provided.

The processing array comprises a network of mutually interconnectable and pre-configurable analog processing slices that form unit circuit cells of the network and that each comprise a set of cell circuit elements. The cell circuit elements of the processing slices are:
a switchable clock input port for receiving a clock signal;
a delay element for receiving a respective analog slice input signal and for forwarding the received slice input signal with a pre-configurable time delay as a respective delayed slice input signal;
an analog multiplier element receiving the delayed slice input signal, for providing an analog multiplier output signal corresponding to a product of the delayed slice input signal with a pre-configurable multiplication factor signal, and
an analog adder element receiving a pre-configurable selection of at least two adder input signals including the multiplier output signal, for providing an analog adder output signal corresponding to a sum of the adder input signals; and
an analog resample element for receiving the adder output signal and for providing the received adder output with a pre-configurable time delay as an analog slice output signal.

Thus, the programmable analog signal processing array of the present invention comprises a network of pre-configurable circuit blocks that provides a programmable in-memory-computing topology implementing a time-discrete analog signal processing approach. The circuit blocks of the network are herein referred to as processing slices. These processing slices of the network all have the described standard circuit structure in common. In other words, they all comprise the switchable clock input, the delay element, the analog multiplier element, the analog adder element and the analog resample element, and they all provide for the basic internal signal flow described above, from the reception of the analog slice input signal on the input side to the provision of the analog slice output signal on the output side of a given processing slice.

On top of this standard cell architecture and standard signal flow characteristics in the analog signal processing array, the individual processing slices provide a multitude of options for slice-individual, i.e., cell-by-cell pre-configuration. The configurability or programmability as used herein includes a re-configurability (re-programmability), i.e., the technical capability of allowing a change from a given configuration to another configuration. Pre-configurability means a capability to set a configuration before the desired signal processing function is to be performed based on a pre-programmed desired configuration. When describing processing slices, their circuit elements, or signal bus structures as pre-configurable herein, this is not meant to exclude, but include as an embodiment a dynamic configurability during operation of the programmable analog processing array in performing the desired signal processing function.

Thus, a programmable (including re-programmable) assignment of cell-individual signal-processing tasks to each processing slice in the overall signal flow of the signal processing for implementing a desired signal-processing function is enabled. Looking at the different options for pre-configuration in more detail, the clock input port is switchable and thus allows an on-off control of the feeding of a clock signal to the processing slice, be it fixed by programming or dynamic by control. Furthermore, the time delay induced by delay element of a given processing slice before providing the respective delayed slice input signal to the analog multiplier element is pre-configurable. This allows controlling the timing of the signal processing task performed by the given processing slice and forms the technical basis for implementing a time-discrete signal processing approach. Also, the multiplication factor, which is applied by the analog multiplier element to the delayed slice input signal is pre-configurable. Furthermore, a selection of zero, one or more adder input signals other than the multiplier output signal is pre-configurable. This enables the provision and processing of further adder input signals beyond the multiplier output signal, for providing an adder output signal having an amount that corresponds to the sum of the adder input signal amounts. Moreover, the provision of the cell-individual adder output signal with a with a pre-configurable time delay as the analog slice output signal provides further programmable timing options for controlling the signal flow between different processing slices.

For comparison, the known processing array of US 2010/0033228 A1 is based on logic cell automata as unit cells of the array. These include logic gates such as AND, OR, and XOR gates, which are implemented in an analog manner to allow determining a probability that a given input signal is “0” or “1”, and to determine an output based on the respective logic function. As an example, an XOR gate of US 2010/0033228 A1 performs a mod2-addition function as known from digital logic gates, but in comparison pure digital logic gates tolerates input signals with a stronger variation in their signal amount. Thus, the processing array of US 2010/0033228 A1 can be described a “soft” digital processing array.

In contrast, the analog signal processing array of the present invention has unit circuit cells in the form of processing slices that comprise analog cell circuit elements, which perform a respective basic arithmetic operation to transform the respective analog slice input signals. As a specific example, the basic arithmetic operations include a multiplication of the (delayed) slice input signal with a pre-configurable factor signal. The signal transformation that is performed by the multiplier element to provide the analog multiplier output signal is a change in the signal amount, which corresponds to the product of the delayed analog slice input signal amount with a pre-configurable multiplication factor. Analog multipliers are frequently used for processing analog signals and form important circuit elements in many signal processing applications including filters, correlators, modulation detectors, and frequency converters. Analog multipliers are also used in forming signals with digital modulation.

Moreover, the analog adder element included in the processing slice performs an addition of the amounts of the analog adder input signals. Adder elements are also used in many signal processing applications, which for example include mixers that add waveforms together from various input channels.

As mentioned above, in contrast to the array of logic cell automata of US 2010/0033228 A1, the processing slices of the programmable analog signal processing array each provide a plurality of pre-configuration options, including, e.g., a pre-configurable selection of the multiplication factor, and a pre-configurable selection of adder input signals. A desired analog signal processing function can thus be implemented by suitable programming of the configuration of the network of processing slices and of its configurable temporal behavior, which includes proper cell-internal delay by the delay element and a suitable cell-output delay by the resample unit, which performs a track-and-hold function for stabilizing the slice output signal, and proper routing control of the signal flow between the different processing slices.

As will be explained in more detail further below in the context of the description of embodiments of the signal processing array of the present invention, a further advantage of the described unique structure of the processing slices is that it allows achieving a defined switching back and forth between signals on a voltage plane and signals on a current plane within the given processing slice. By way of example, the analog multiplier element can be configured to switch from a voltage plane of the delayed slice input signal to a current plane of the multiplier output signal, and the analog resample element can be configured to switch from a current plane at an output of the analog adder element back to a voltage plane, such that the analog slice output signal is on the same voltage plane as the slice input signal. This way, a freely configurable interconnectability of the processing slices among each other all over the analog fabric formed by the network of processing slices is ensured.

In comparison with digital programmable processing arrays such as field programmable gate arrays, the analog signal processing array of the present invention achieves the advantage that no increase of hardware expenditure is required for achieving a higher signal resolution because the received signals are processed in the analog domain.

Furthermore, the programmable analog signal processing array implements an in-memory-computing approach in that data to be processed are represented by analog signals that are routed according to a programmed signal processing flow and need not be stored in a memory and read before processing.

Preferred embodiments of the analog signal processing array further comprise a pre-configurable analog signal bus for receiving and providing the analog input signals to the network of processing slices and for interconnecting any given processing slice to one or more respective other of the processing slices of the network of processing slices to transport the slice input signals and slice output signals. The signal communication within the network of processing slices during the signal processing operation is thus based on a bus infrastructure. Throughout the present specification and in the claims, the term “bus” is used to denote a means of signal communication between two or more processing slices. As such, a bus forms an electrical interconnect system that can be implemented in different forms. In its simplest form, a bus can be formed by a point-to-point signal connection between two processing slices. In preferred, more complex embodiments, a bus comprises a configurable network of electrical interconnect segments that can be interconnected by means of a switching infrastructure according to a pre-configurable bus configuration. The pre-configurable analog signal bus in the form of such a pre-configurable network of interconnects between processing slices allows implementing any desired connections between processing slices as well as blocking undesired connections between processing slices, in accordance with a programmable configuration that serves to implement the desired signal processing function. The analog signal bus of some embodiments provides interconnections between processing slices to form one or more meshed signal interconnect networks.

The analog signal bus of some embodiments suitably comprises different bus components, including
a first signal bus, hereinafter analog in-out bus, for receiving the slice input signals and routing them to a pre-configurable set of processing slices and for receiving the slice output signals of the processing slices in accordance with the signal-bus configuration;
a second signal bus, hereinafter multiplier bus, for receiving the respective delayed slice input signals and routing them to a pre-configurable set of processing slices in accordance with the signal-bus configuration;
a third signal bus, hereinafter adder bus, for receiving the respective multiplier output signals and routing them to a controllable set of processing slices in accordance with the signal-bus configuration;
a fourth signal bus, hereinafter adder output bus, for receiving the respective adder output signals and routing them to a pre-configurable set of resample elements in accordance with the signal-bus configuration.

The analog in-out bus, the multiplier bus, the adder bus and the adder output bus are each switchably interconnectable with each of the processing slices in accordance with the signal-bus configuration. Analog signals transported on any one of the bus components of the analog signal bus for performing the desired signal processing function are herein also summarized under the generic term analog data signals. Thus, this includes the slice input signals, slice output signals, delayed slice input signals, multiplication factor signals, multiplier output signals, adder input signals, and the adder output signals.

Preferred embodiments additionally comprise a configuration-signal bus for receiving and routing respective configuration control signals to the individual processing slices, wherein the respective configuration control signals are for configuring
individual time delays of the respective delay elements,
individual multiplication factors of the respective multiplier elements,
individual selections of adder input signals to the respective adder elements, and
individual switchable interconnections of the respective processing slices to the analog signal bus for routing, in accordance with a programmable signal-bus configuration and with the signal processing function, the input signals, the respective slice input signals, and the respective slice output signals between the processing slices via the analog signal bus;
and, connected to the network of processing slices,
individual switching states of the clock input ports for allowing or blocking the provision of the clock signal to the respective processing slice.

Such embodiments suitable comprise in addition a configuration control unit for receiving a configuration code and for using the configuration code to generate the configuration control signals to configure the network of processing slices for implementing an analog signal processing circuit that in operation performs the desired signal processing function.

Thus, the configuration control unit uses the received configuration code to build the analog signal processing circuit from the “raw” building blocks provided by the programmable analog signal processing array. The configuration control signals are generated and provided to the processing slices including their switchable interconnections to the analog signal bus in a suitable form to set, or, in other words, program the respective configuration for implementing the desired signal processing circuit into the analog signal processing array.

This configuration scheme for the analog signal processing array of the present embodiment forms a “digital-like design flow” and is thus easy to use for the circuit designer. Digital design flows combine well known automation tools in the design of an integrated circuit, which involve, among others, synthesis, placement and routing algorithms.

The following turns to the advantageous capability of embodiments of the processing slices to allow switching back and forth between a voltage plane and a current plane. In some embodiments, the delay element of the programmable analog signal processing array is configured to receive the respective analog slice input signal as a first analog voltage signal and to provide the respective delayed slice input signal as a second analog voltage signal. Moreover, the analog multiplier element is configured to provide the analog multiplier output signal as a first analog current signal, and the analog adder element is configured to receive the at least two adder input signals as analog current signals and to provide the analog adder output signal also as an analog current signal of an amount indicative of the sum of the adder input signals. Furthermore, in such embodiments, the resampling element suitably comprises a current-to-voltage converter for receiving the analog adder output signal and for providing an adder output voltage signal of an output voltage amount indicative of the current amount of the analog adder output signal as the slice output signal. This embodiment achieves that a voltage plane of the slice output voltage signal of the current-to-voltage converter is the same as that of the slice input signal received by the delay element. This embodiment ensures a freely configurable interconnectability of the processing slices among each other.

However, to achieve such freely configurable interconnectability of the processing slices, it is not a requirement to use exactly the structure of the corresponding embodiments described. It is a requirement only, that the output of the resample element is of the same signal type as the slice input signal. Other processing slice designs can be suitable to achieve this. For instance, the analog adder element may provide the adder output signal in the form of a voltage signal and not of a current signal. In this case, the resample element does not need to perform current-to-voltage conversion for providing the slice output signal. In another variant, the multiplier element may provide the multiplier output signal in the form of a voltage signal and not of a current signal, and the analog adder element may thus be configured to add received input voltage signals.

Another embodiment of the analog signal processing array further comprises a configuration input port for receiving hardware configuration data defining, using e.g. a hardware description language, a structure and behavior of an analog signal processing circuit performing a signal processing function to be implemented by the programmable analog signal processing array. Furthermore, this embodiment comprises a configuration processor for transforming the hardware description data into net list data indicative of a net list of processing slices and for transforming the net list data into place-and-route data indicative of place-and-route information to be implemented using the network of processing slices and determining desired interconnections of the processing slices that implement the analog signal processing circuit, and for transforming the net list and the place-and-route data into the configuration code. The configuration code thus represents topological data that specifies the topology of the signal processing circuit to be implemented by the programming of the analog signal processing array.

This embodiment advantageously enables a programming of the analog signal processing array in the same manner as it is known from field programmable gate arrays in the digital domain and thus allows making use of well-implemented and advanced design procedures, which facilitates an easy integration of the advantageous performance of the programmable analog signal array into existing digital data and signal processing design workflows, without requiring the designer to learn new design methodologies.

This embodiment is particularly suited for use in further developed embodiments that include an arrangement of digital and analog processing arrays, and thus integrate a digital part including a field programmable gate array with an analog part that includes an analog signal processing array according to the present embodiment. The inclusion of a digital part with a field programmable gate array enables an integration of “classical” digital processing slices such as look-up tables, digital adders, digital multipliers, serializer-deserializer (SerDes) elements and others with the in-memory-computing topology that is provided by the programmable analog signal processing array. A change between the analog domain of the analog signal processing array and the digital domain of the digital field programmable array can be achieved by routing the respective analog or digital signals via analog-to-digital converters or digital-to-analog converters where necessary.

Analog circuit elements and processing slices may vary in their signal processing characteristics even if they are nominally identical. Preferred embodiments mitigate this issue by using a further developed configuration processor that is further configured to generate, using the hardware description data, desired slice response data that is indicative of individual desired delayed slice input signals of the respective cell circuit elements of the individual processing slices in response to one or more predetermined analog configuration test signals. In a variant of this embodiment, it is not the configuration processor that generates the slice response data, but a different processor, which is referred to as configuration test processor, and the configuration processor forwards the received hardware description data to the configuration test processor. In another variant, the hardware description data is directly provided to the configuration test processor, via a data connection that is parallel to that feeding the configuration processor with the hardware description data.

These embodiments additionally comprise an analog test bus, which is connected with the configuration control unit and which is connectable with the individual processing slices to provide them with the one or more analog configuration test signals generated by the configuration control unit and to provide the configuration control unit with respective individual slice test-response signals provided by the respective cell circuit elements of the processing slices, each in response to the one or more configuration test signals.

The configuration control unit is suitably configured to generate the one or more predetermined configuration test signals and to determine deviations of the received slice test-response signals from the desired slice response data in accordance with predetermined deviation criteria, and in case of determining a deviation for a given processing slice, to generate the adapted configuration data for the respective processing slice and use the adapted configuration data for providing one or more adapted configuration signals to the respective processing slice. In a variant, the configuration processor is additionally configured to add the adapted configuration data to the configuration code, for instance in the form of calibration data that represent corrections to be applied to nominal circuit-element configuration data. For instance, weight factor corrections may be applied to individual analog multiplier elements due to determined deviations from nominal weight factor values, caused, e.g., by production inaccuracies or fluctuations.

Another embodiment of the programmable analog processing array further comprises a configuration memory for storing the net list, the place-and-route data, the configuration code, the configuration data and, if provided, the adapted configuration data. Such adapted configuration data can be determined and stored in a calibration routine during production of the programmable analog signal processing array. In contrast to configuration data representing static topological data, adaptable configuration data may also be determined by the configuration control unit or the configuration processor by performing a background calibration process while the analog signal processing array is otherwise operative in performing the signal processing function.

The configuration control unit is thus configured to use the configuration code for generating respective configuration signals that establish desired electrical connections between the processing slices. Suitably, processing slices may have associated control elements that receive configuration signals associated with the processing slices from the configuration control unit for controlling a routing of
the configuration signals to the respective processing slices;
the configuration test signals associated with the processing slices and the slice test-response signals in response to the configuration test signals from the processing slices via the analog test bus,
the clock signal to the respective processing slices; and of
analog data signals between the processing elements of the processing slices via the analog signal bus.

The control elements can be implemented as control registers or look-up tables receiving and storing suitable configuration signal information in digital form from the configuration control unit and feeding the corresponding configuration signals to the respective switching elements and circuit elements of the processing slices. If required, e.g. when configuring the multiplication factors or calibration weighting factors, a DAC or other suitable transformation element can be used to generate the configuration signals from the stored configuration signal information.

The following turns to embodiments having different implementations of the analog multiplier element. In one embodiment, the multiplier element of the processing slices comprises a configurable memristor, which receives the delayed slice input signal and which is configured to provide the multiplier output signal as a current signal of a current amount that is indicative of a product of an input voltage amount of the delayed slice input signal multiplied by the received multiplication factor signal. The configurability refers to the determination of a weight factor to be applied in the multiplication. The use of a memristor in an analog multiplier element is per se known. The configuration of the multiplication factor effected by the memristor is achieved using a configuration signal provided to the memristor. The configuration signal causes a change in a state variable of the memristor. The change in the state variable of the memristive device results in the output of a product of the input signal with the configured multiplication factor.

In a further development of this embodiment, the configuration control unit is configured to use the configuration input data or, if present, the adapted configuration data to determine respective memristor configuration signal amounts to be applied to the respective memristor of the multiplier elements of the individual processing slices to set or adapt a respective multiplication factor of the respective multiplier element, and to subject the respective memristor of the multiplier elements to the determined configuration signal of the determined configuration signal amount.

Depending on the particular implementation of the memristor, the configuration signal can be a current or a voltage. Other physical quantities, however, may also be useable for implementing the configuration signal.

The multiplication factor of an analog multiplier element using a memristor may be subject to undesired variation over the course of analog signal processing operation. To compensate for undesired variations in the signal processing, a background calibration of the memristors is provided in a further embodiment. In this embodiment, the configuration control unit is configured
to switch to an intermittent background calibration mode under a signal processing operation of the processing array, and, in the background calibration mode,
to generate and provide via the analog test bus one or more multiplier test signals to the multiplier elements,
to determine from the received multiplier output signals a deviation of a respective multiplication factors from the respective desired multiplication factors according to the configuration code; and, in case of a determining a deviation,
to generate and provide a respective memristor re-configuration signal amount to be applied to the respective memristor of the multiplier elements of the individual processing slices in order to re-set the respective multiplication factor of the respective multiplier element to the desired value; and
to subject the respective memristor of the multiplier elements to the determined respective reconfiguration signal amount.

In alternative embodiments of the processing slice the multiplier element of the processing slices comprises a field effect transistor (FET) as the active component instead of a memristor. If operated in a linear range at a suitably low drain-source voltage, the FET represents a controllable resistive element that can be controlled via a control voltage to be applied to its gate electrode.

A control voltage determining the multiplication factor is applied to the gate electrode of the FET. In operation, for example, the FET receives an input voltage signal of the delayed slice input signal at the source electrode, and provides an output current signal corresponding in its amount to the a mount of a product of the input voltage signal and the configured multiplication factor. The drain electrode is suitably connected to the current bus to provide the output current signal. Here, thus, the configurability refers to the selection of the multiplication factor entering in the multiplication by suitably controlling the voltage applied to the gate electrode of the FET.

In a further development of this embodiment, the configuration control unit is configured to use the configuration input data or, if present, the adapted configuration data to determine respective FET configuration signal amounts to be applied to the gate electrode of a given FET of the multiplier elements of the individual processing slices to set or adapt a respective multiplication factor to be applied by the respective multiplier element, and to apply the determined configuration signal of the determined configuration signal amount during signal processing operation. The determined signal can be applied by storing a digital representation of the configuration signal in a configuration register or configuration register area associated with the multiplier element, and feeding it to the respective multiplier element via a DAC.

In other embodiments, the analog multiplier is implemented as an analog multiplier circuit known per se, which receives the delayed slice input signal and is configured to provide as an output a product of the delayed slice input signal with a multiplication factor that is pre-stored in digital form in a register and fed to the multiplier circuit via a digital-to-analog converter. For instance, analog multiplier topologies such as those known from a Gilbert cell are suitable for use in a processing slice.

In some embodiments, the network of processing slices is partly or completely divided into identical macrocells that each comprise a plurality of processing slices. Macrocells may have a different granularity in different embodiments. A particularly small macrocell may be made of only two processing slices. In other embodiments, a macrocells comprises up to ten, up to 50, or up to 100 processing slices.

To enable a programmable configuration of the macrocells, the configuration control unit is configured to use the configuration code for generating respective configuration signals that establish desired electrical connections between the processing slices of a given macrocell. Each of the macrocells has an associated control element that receives the configuration signals associated with the processing slices of the given macrocell from the configuration control unit for controlling a routing of
the configuration signals to the respective processing slices of the given macrocell,
the configuration test signals associated with the processing slices of the given macrocell and the slice test-response signals in response to the configuration test signals from the processing slices of the given macrocell via the analog test bus,
the clock signal to the respective processing slices of the given macrocell; and/or of
analog data signals between the processing elements of the processing slices via the analog signal bus.

The time-discrete computing approach can be implemented in different ways. One group of embodiments of the programmable analog signal processing array comprises a clock generation unit that is configured to generate a pair of two-phase non-overlapping clock signal trains to the processing slices via the clock bus. In this group of embodiments, one way of implementing the pre-configurable delay element of the processing slices involves a series of at least two switching elements that receives the slice input signal. Each of the switching elements also has a control gate receiving a respective one of the clock signal trains for opening and closing the switching element in accordance with the two phases of the respective clock signal train. The delay element further comprises parallel capacitances respectively arranged, in a direction of signal flow, behind each switching element, for providing the delayed slice input signal behind the last switching element in the direction of signal flow.

In a variant under this group of embodiments, only a single two-phase clock signal train is generated originally, and a suitable separate circuit, which is per se known, receives this clock signal train and uses it to generate the second, clock signal train in a non-overlapping manner with the first train. One example of this variant uses an inverter upstream of the control gate of the second switching element to generate the second clock signal train.

A second group of embodiments involves an operation of the entire array of processing slices with asynchronous handshake signals, e.g., using a 4-phase handshake without any clock signal. This reduces or fully avoids unwanted influences of the clock signal on the analog signal values, for instance capacitive couplings, or dips of the operating voltage. In this second group of embodiments, the analog signal bus is associated with and controlled by at least one handshake line for transporting communication control signals between the processing slices in accordance with a handshake protocol. The processing slices or, if present, macro cells each further comprise an associated handshake circuit which is configured to
generate and provide communication control signals on behalf of the respective associated processing slice or macrocell for asynchronous communication with other processing slices or macro cells of the network of processing slices or macro cells in accordance with a handshake protocol;
control the time delay in providing the delayed slice input signal by the delay element, and to
control a timing of an output of the multiplier output signal, or of the adder output signal via the signal bus in response to a protocol exchange with at least one target processing slice in accordance with the handshake protocol.

Further embodiments will be presented in the context of the following description of the enclosed drawings.

### BRIEF DESCRIPTION OF THE DRAWINGS

In the drawings:

FIG. 1 is a block diagram illustrating a high-level structure of a programmable analog signal processing array according to an embodiment of the present invention;

FIG. 2 is a block diagram of a processing slice that forms an elementary circuit cell of a programmable analog signal processing array according to an embodiment of the present invention;

FIG. 3 is a block diagram of an exemplary programmable macrocell of processing slices for use in an analog processing array of the type shown in FIG. 1;

FIG. 4 is a block diagram illustrating a high-level structure of a programmable analog signal processing array 400 according to a further embodiment of the present invention;

FIG. 5 is a diagram illustrating the configurability of access control between the processing slice of FIG. 2 and an analog test bus;

FIG. 6 is a simplified circuit diagram of a section of an analog processing array, the section showing two processing slices;

FIG. 7 is a circuit diagram of a delay element and an analog multiplier element suitable for use in a processing slice of a programmable signal processing array of the present invention;

FIGS. 8 to 10 show an alternative implementation of an analog multiplier element in the form of a field effect transistor;

FIG. 11 shows a circuit diagram of an exemplary analog adder element suitable for use in a processing slice;

FIG. 12 shows a circuit diagram of another exemplary adder element suitable for use in a processing slice;

FIG. 13 is a circuit diagram of another exemplary analog multiplier element for use in a processing slice;

FIG. 14 is a circuit diagram of another exemplary analog multiplier element for use in a processing slice;

FIG. 15 is a schematic illustration of a another embodiment of a processing slice that uses a true-time delay element ; and

FIG. 16 is an illustration of a further implementation of a controllable delay element that uses a handshake concept in the signal communication between processing slices.

### DETAILED DESCRIPTION OF EMBODIMENTS

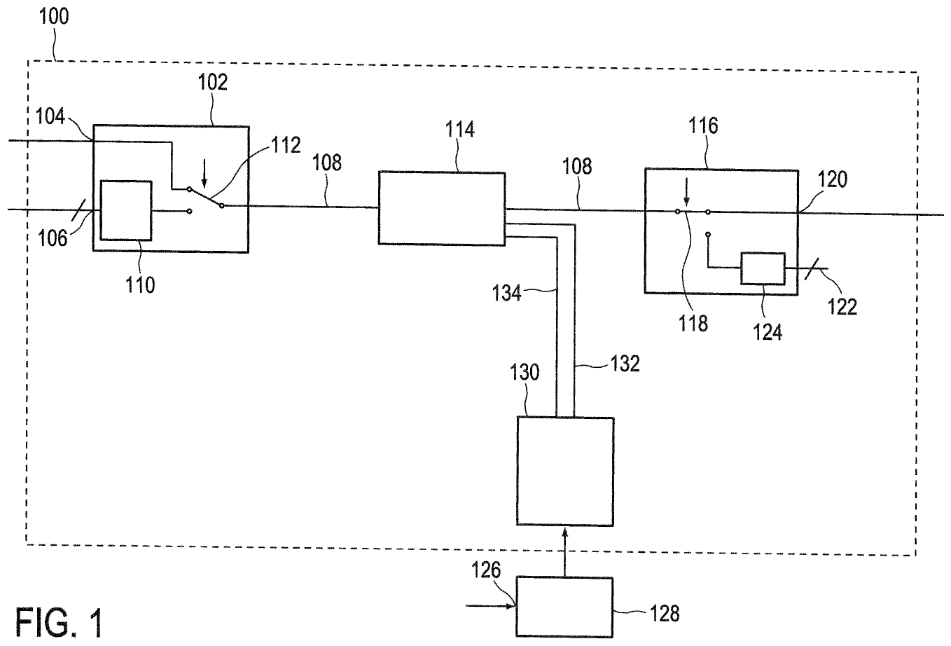

FIG. 1 is a block diagram illustrating a high-level structure of a programmable analog signal processing array 100 according to an embodiment of the present invention. The programmable analog signal processing array will hereinafter also be referred to in short as PASPA.

The PASPA 100 comprises in an input unit 102 with an analog signal input port 104 and a digital signal input port 106. The analog signal input port 104 is configured for receiving analog input signals. In different variants of the present embodiment, the input port is configured to receive one or more analog input signals in parallel. Depending on a bus width of an analog signal bus that forwards the analog input signals received in parallel by the analog signal input port 104, the analog signal input port 104 may distribute the received analog input signals directly to the bus lines, or via one or more multiplexer (not shown).

In the present embodiment, the analog input signals are analog voltage input signals. In other embodiments, the analog signal input port 104 receives analog current input signals and comprises a current-to-voltage converter (not shown), for instance including a transimpedance amplifier.

In the present embodiment, the input unit 102 additionally comprises the digital signal input port 102, which is configured to receive signal words with a plurality of bits in parallel. The digital signal input port further comprises a digital-to-analog converter (DAC) 110 which receives the incoming digital signal words and converts them to analog voltage signals of an amount corresponding to that indicated by the received signal word and provides them to the analog signal bus 108. A controllable switch 112 serves to select one from the analog and digital signal input ports 104 and 106 for feeding the received input signals to the analog signal bus 108 at a given point in time. Details of the control structure for providing a suitable time-dependent control signal to the switch 112 are not shown here.

It should be noted that the provision of a digital signal input port 106 is an optional feature that increases the versatility of the PASPA 100 by adding an option of receiving and processing digital input signals. However, other, simpler embodiments only have the analog signal input port 104 and no digital signal input port.

The analog signal bus 108 forwards the received input signals in analog form to an analog processing array 114. The analog signal bus 108 can be compared to a data bus that transports the data to be processed

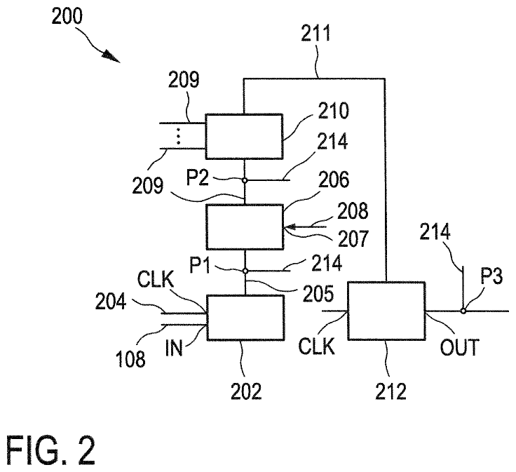

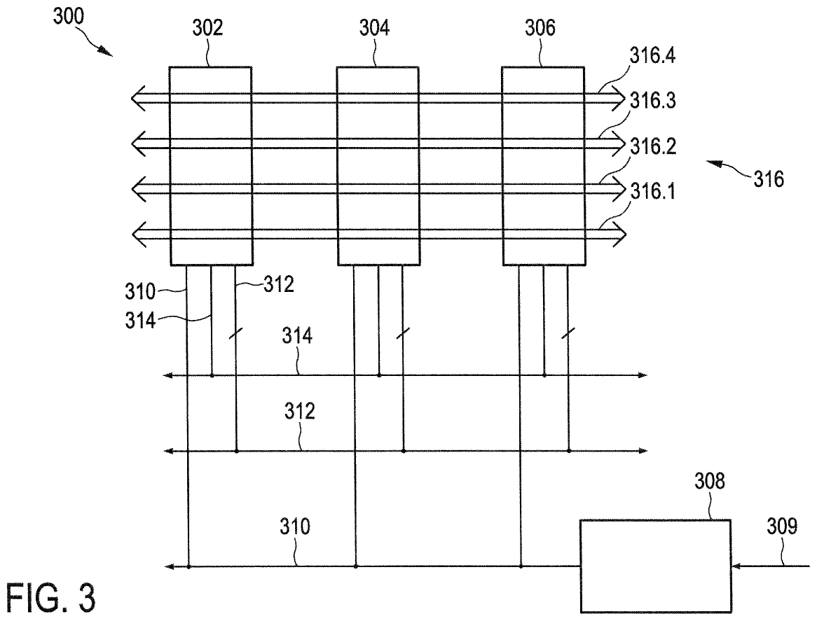

The analog processing array 114 is made of a network of mutually interconnectable and pre-configurable or, in other words, programmable analog unit circuit cells, which herein are referred to as processing slices. The number of processing slices depends on the desired signal processing capacity and typically exceeds ten thousand processing slices. In embodiments with higher signal processing capacity, the number of processing slices exceeds fifty thousand, one hundred thousand, or even one million processing slices. The network of progammably interconnectable processing slices can also be described as an analog processing fabric. Details of the structure of the analog processing array 114 will be described further below with reference to the embodiments shown in FIGS. 2 and 3.

Output of the analog output signals of the analog processing array 114 is provided via an output unit 116 that comprises a controllable output selection switch 118, which selects between an analog output via analog output port 120, or a digital output via a conversion by analog-digital converter 124 and a digital output port 122.

A configuration processor 128 that is external to the analog signal processing array 100 comprises a configuration input port 126 for receiving hardware description data defining, using a hardware description language, a structure and behavior of an analog signal processing circuit performing a signal processing function and to be implemented by the programmable analog signal processing array 100. The configuration processor 128 is provided for transforming the hardware description data into net list data indicative of a net list of processing slices and for transforming the net list data into place-and-route data indicative of place-and-route information to be implemented using the network of processing slices and determining desired interconnections of the processing slices that implement the analog signal processing circuit, and for transforming the net list and the place-and-route data into configuration code. The configuration code thus represents topological data that specifies the topology of the signal processing circuit to be implemented by the programming of the analog signal processing array.

The programmable signal processing array 100 comprises a configuration control unit 130 for receiving the configuration code from the external configuration processor 128 and for using the received configuration code to generate configuration control signals and provide them to the signal processing array 114 via a control bus 132 to configure the network of processing slices of the analog processing array 114 for implementing an analog signal processing circuit that in operation performs the desired signal processing function. The configuration control signals are provided to the processing slices including their switchable interconnections to the analog signal bus in a suitable form to program the respective configuration for implementing the desired signal processing circuit into the analog signal processing array. This process is generally known from the configuration and programming (sometimes in colloquial terms described as “burning”) of digital processing circuits in FPGAs. A suitable current or voltage amount can be used to configure a given circuit property, depending on the particular hardware implementation. This configuration scheme for the analog signal processing array can be described as a “digital-like design flow”. For the circuit designer, no substantial deviation from his or her design process is required, and use of well-known automation tools in the design of an integrated circuit using an FPGA can be expanded correspondingly to program the analog processing array 114.

Furthermore, an analog test bus 134 connects the configuration control unit 132 with the signal processing array 114 to feed analog configuration test signals generated by the configuration control unit 130 and to provide the configuration control unit 130 with respective individual test-response signals provided by the respective cell circuit elements of the processing slices of the signal processing array 114 in response to the configuration test signals. This will be explained in more detail in the context of the embodiment of FIG. 2.

Embodiments of the PASPA 100 are implemented as a single integrated-circuit package. Other embodiments are implemented by means of a circuit board that comprises different integrated circuit packages connected to form the PASPA.

Variants of embodiment of FIG. 1 comprise the configuration processor 128 as an internal unit of the PASPA 100, for instance as a separate processor chip on a circuit board shared with a chip of the configuration control unit 130, and, optionally, also shared with the analog signal processing array 114 and its periphery, in particular the input unit 102 and the output unit 116.

For a closer look at the structure of the individual processing slices of the analog processing array 114, additional reference is now made to FIG. 2. FIG. 2 is a block diagram of a processing slice 200 that forms a unit circuit cell or standard cell of the analog processing array 114 according to an embodiment of the present invention. Typically, all processing slices comprise the same set of cell circuit elements, which are shown in FIG. 2. However, other embodiments have more than one type of processing slices.

A first cell circuit element of the processing slice 200 is a pre-configurable delay element 202. It has a switchable clock input port CLK for receiving a clock signal via a clock bus 204 (not shown in FIG. 1). For reasons of graphical simplification, a controllable switch for on-off control of the feeding of the clock signal via the clock input port CLK is not shown in FIG. 2. Also, an array-internal control bus connected to the control bus 132 for providing the control signal to the controllable switch is not shown here. Beside the clock signal, the delay element 202 further receives an analog slice input signal from an analog signal bus 108 via a slice signal input port IN. Depending on the pre-configured routing of signals, the slice input signal may be one of the input signals received by the input unit 102, or an analog slice output signal provided by another processing slice.

The delay element 202 is configured to provide a delayed slice input signal that, except for the imposed delay, otherwise corresponds to the received slice input signal. An amount of the delay of the delayed slice input signal in comparison with the received slice input signal is pre-configurable. It can be controlled by means of the on-off control of the clock signal received at the clock input port CLK. Imposing a delay of a pre-configured amount in terms of a single clock period or multiples of a clock period supports a time-discrete signal processing scheme. Details of different implementations of the delay element 202 will be shown further below.

A multiplier bus 205 connects the delay element 202 with a second cell circuit element of the processing slice 200, which is an analog multiplier element 206. In the present embodiment, the analog multiplier element 206 has a multiplier configuration input 207 that is connected to the array-internal section of the control bus 208 for setting a pre-configurable multiplication factor that enters the signal multiplication performed by the multiplier element 206.The analog multiplier element 206 receives the delayed slice input signal and is configured to provide an analog multiplier output signal corresponding to a product of the delayed slice input signal and the pre-configurable multiplication factor. The multiplication factor is received via the multiplier configuration input 207. The function of an analog multiplier element is per se known in the art. Depending on the specific implementation of the multiplier element 206, the multiplier output signal is an analog current signal or an analog voltage signal. Exemplary implementations of analog multiplier elements will be described further below.

An adder bus 209 connects the output of the multiplier element 206 with one input of an analog adder element 210, which forms a third circuit element of the processing slice 200. The analog adder element 210 receives a pre-configurable selection of at least two adder input signals via a corresponding number of different signal lines of the adder bus 209. Thus, at least one of the signal lines of the adder bus 209 carries the multiplier output signal of the multiplier element 206 as one of the adder input signals. The other signal lines of the adder bus 209 are available for providing adder input signals generated by different processing slices, as required for performing a desired signal processing function. The analog adder element 210 is configured to provide an analog adder output signal that corresponds to a sum of the received adder input signals. An exemplary implementation of an adder element 210 will be presented further below. Depending on the implementation of the adder element 210, the adder output signal is an analog current signal or an analog voltage signal.

Finally, an analog resample element 212 is provided as a fourth circuit element of the processing slice 200. It receives the adder output signal via a resampler bus 211, and a clock signal, and provides the received adder output signal with a pre-configurable time delay as an analog slice output signal of the processing slice 200 at a slice signal output port OUT.

To facilitate networked processing involving a sequence of processing steps performed by a plurality of interconnected processing slices, the analog slice output signal provided at the slice signal output port OUT is suitably provided in the form of a physical quantity that is the same as that of the slice input signal received at the slice signal input port IN. In present embodiment, for instance, if the analog input signal is received as an analog voltage signal at the slice signal input port IN, the slice output signal is provided by the resample element 212 at the slice signal output port OUT as an analog voltage signal as well. As an example, in case the adder output signal is an analog current signal, the resample element 212 is configured to convert the incoming adder output signal to a voltage signal having a voltage amplitude indicative of the current amplitude of the adder output signal, and having the pre-configurable time delay. Three test access points P1, P2 and P3 allow access to respective an array-internal section of an analog test bus 214 that serves to feed analog configuration test signals generated by the configuration control unit 130 (cf. FIG. 1) and to provide the configuration control unit 130 with respective individual slice test-response signals provided by the respective cell circuit elements of the processing slice in response to the configuration test signals. As an example of the use of the analog test bus 134, 214 and the test access points, a configuration test signal can be fed to the analog multiplier element 206 via the array-external and array-internal analog test bus sections 134, 214 to access point P1, suitably in a test phase outside actual operation of the signal processing function, along with a pre-determined multiplication factor that is provided to the multiplier element 206 via multiplier configuration input 207. A multiplier test output signal can then be picked up via access point P2, fed back to the configuration control unit 130 and evaluated. The evaluation by the configuration control unit 130 determines whether the factor currently applied by the analog multiplier element 206 is correct for performing the desired multiplication in the context of the signal processing function. A correct functioning of the analog adder element 210 and the analog resample element 212 can be determined in a similar manner.

The analog test bus is structured to allow an individual addressing of each of the test access points in each of the processing slices. FIG. 2 does not show switching elements that control an access state of the test access points P1 to P3 (open/closed, feeding/receiving).

Performing such a test phase for the processing slice 200 is possible even during actual operation of the signal processing function if the current operational state of the signal processing circuit does not involve any contribution by the processing slice 200. This way, a re-calibration of the processing slice 200 can be performed even while the signal processing operation is ongoing.

FIG. 3 is a block diagram of an exemplary programmable macrocell 300 of processing slices for use in an analog processing array of the type shown under reference label 114 in FIG. 1. The exemplary macrocell 300 comprises three processing slices 302, 304 and 306, which are of the same type as the processing slice 200 shown in FIG. 2. The number of processing slices shown in FIG. 3 is selected for exemplary illustration only. Macrocells may have a different granularity in other embodiments. Macrocells may comprise up to 100 or even up to 1000 processing slices. The number of processing slices in a macrocell is not limited by these examples, but can be determined in view of the requirements of a particular set of application cases to be covered by a given type of PASPA. The number of processing slices per macrocell need not be the same for all macrocells of a given PASPA.

Since the circuit elements of the processing slice 200 are shown in FIG. 2 and have been described above in detail, the present graphical representation omits the details of the internal circuit structure of the processing slices 302 to 306.

To enable the programmable configuration of the macrocell 300, a control element 308 is provided in association with the macrocell 300 and connected with the processing slices 302, 304, and 306 of the macrocell via a macrocell-internal control bus 310. The control element 308 is associated in its control function with the given macrocell 300 and may thus be considered as performing a “satellite” control function under the central control of the configuration control unit 130. The control element 308 comprises a control register for storing applicable configuration signal information. The control register of the control element 308 is programmed and addressed via a global control bus 309 running over the entire PASPA. The programming is performed by the configuration control unit 130 (cf. FIG. 1) via the global control bus 309. Suitably, the configuration control unit 130 thus performs the programming of all macrocells of the PASPA.

In the advantageous layout approach shown in FIG. 3, the control elements 308 of the different macrocells 300 of a PASPA are thus distributed across the processing array and are suitably arranged in local proximity to their respective associated macrocell 300.

In an alternative approach (not shown), the different control elements are spatially grouped together or even implemented in an integrated circuit in a control section of the array that may even be combined with the control unit 130 shown in FIG. 1. In both layout approaches, the control signal flow to the associated macrocell via the control bus 309 suitably involves an identification of the individual macrocell, and may even reach down to the level of an identification of an individual processing slice or a respective switching element or circuit element to be configured with a given configuration control signal.

Furthermore, the processing slices 302 to 306 of the macrocell 300 are each connected to an analog test bus 312. The analog test bus is connected with the configuration control unit 130 to provide the processing slices of the macrocell 300 with analog configuration test signals generated by the configuration control unit. Also, respective individual slice test-response signals provided by the respective cell circuit elements of the processing slices, in response to the one or more configuration test signals are provided back via the analog test bus 312 for evaluation and potential adaptation of the configuration. Such evaluation and adaptation of the configuration is performed by the configuration processor 128.

A clock tree 314 provides a clock signal to the processing slices of the macrocell 300. Moreover, the analog signal bus 316 of the present embodiment includes four different signal bus components, which generally correspond to the signal bus components described in the context of FIG. 2:
A first signal bus component, herein analog in-out bus 316.1, for receiving the slice input signals and routing them to a pre-configurable set of processing slices and for receiving the slice output signals of the processing slices in accordance with the signal-bus configuration;
A second signal bus component, herein multiplier bus 316.2, receives the respective delayed slice input signals and transports them to a pre-configurable set of processing slices in accordance with the signal-bus configuration, to form respective multiplier input signals for these processing slices;
A third signal bus component, herein adder bus 316.3, receives respective multiplier output signals and routes them to a controllable set of processing slices in accordance with the signal-bus configuration, to form respective adder input signals for these processing slices; and
A fourth signal bus component, herein a resampler bus 316.4 receives the respective adder output signals and transports them to a pre-configurable set of resample elements in accordance with the signal-bus configuration.

Switching elements for static or dynamic control of the routing of the analog data signals on the analog signal bus 316, the clock signal train on the clock tree 312 and the signals on the analog test bus 314 to and between the individual circuit elements of the processing slices 302, 304 and 306 are provided, but not shown here for reasons of graphical simplicity. The control element 308 and the control bus 310 serve for controlling the respective switch settings for establishing desired connections of the circuit elements of the processing slices within the macrocell 300, and the routing of the different signals among them.

Signal communication between different processing slices is possible via each of the four signal bus components 316.1 to 316.4. As an example, an analog slice input signal may be routed to a first processing slice, and the only signal processing task of the first processing slice may be to subject the analog input signal a controlled time delay of a predetermined number of clock cycles. In this exemplary case, the delayed slice input signal will be routed from the delay element of the first processing slice to back to analog in-out-bus 316.1 and output to a predetermined next processing slice in the signal processing flow. Switching elements suitably arranged along the analog in-out bus 316.1 can be used to avoid any undesired signal “collisions” of the delayed slice input signal with other analog slice input signals received by the first processing slice via the in-out bus 316.1.

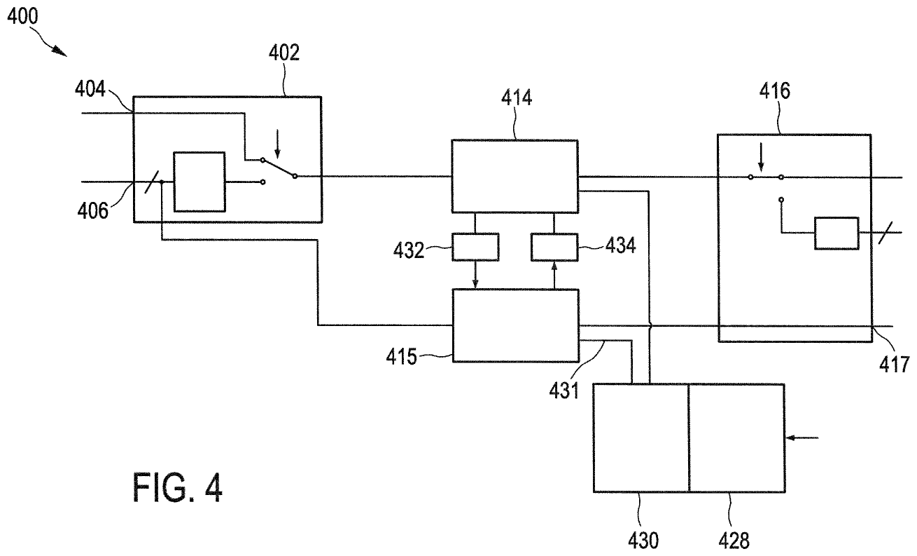

FIG. 4 is a block diagram illustrating a high-level structure of a PASPA 400 according to a further embodiment of the present invention. The following description will concentrate on the differences of the PASPA 400 in comparison with the PASPA 100 shown in FIG. 1. Reference labels that point to elements of the PASPA 400 that correspond to elements already described in the context of FIG. 1 either share the last two digits with those elements or carry no reference label at all. For a more detailed description of these elements of the PASPA 400, reference is thus made to the description of the corresponding elements in FIG. 1.

The PASPA 400 comprises in an input unit 402 with an analog signal input port 404 and a digital signal input port 406. In the present embodiment, the input unit 402 is configured to not only forward received input to the analog processing array 414, but to additionally forward selected received digital data signal words to a programmable digital signal processing array (PDSPA) 415. A suitable switching unit for controlling a selection of digital data words to be forwarded to the PDSPA 415 is not shown here. The PDSPA 415 comprises a programmable network of digital logic gates. In one implementation, digital signal processing array 415 comprises a field programmable gate array (FPGA), as it is per se known in the art. The PDSPA 415 is in one embodiment an integrated component of the PASPA 400, which thus forms a system on chip with an analog processing array 414 and a digital processing array 415. However, other embodiments have the analog processing array 414 and the digital processing array 415 separate chips, suitably in the form of a system in package, or in an arrangement of chips together with peripheral circuitry on a printed circuit board.

Data exchange between the analog processing array 414 and the digital processing array 415 is performed via an analog-to-digital converter (ADC) 432 and a DAC 434. Thus, the PASPA 400 allows efficiently combining the advantages of digital and analog signal processing in a single programmable signal processing array. The programming of both the analog processing array 414 and the digital processing array 415 can be performed using an identical configuration processor 428 and an identical configuration control unit 430. An additional digital configuration control bus 431 provides the configuration signals to the PDSPA 415. As indicated before, it is particularly advantageous that the design process for programming the analog processing array 414 and the digital processing array 415 is substantially identical and thus achieves integration of the design flow of a combined analog and digital signal processing application. The output unit 416 is extended in comparison with that of the embodiment of FIG. 1 by an additional digital output port 417 for the digital output data provided by the PDSPA 415.

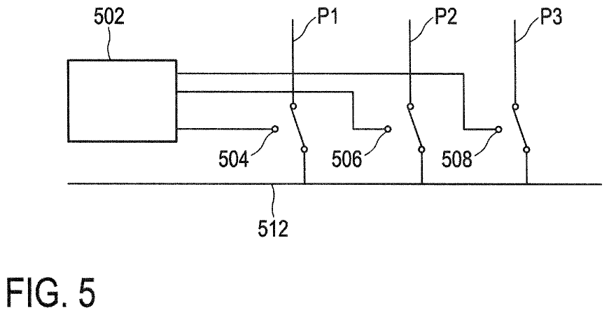

FIG. 5 is a diagram illustrating the configurability of access control between the processing slice of FIG. 2 and the analog test bus. A test switching control register 502 provides control information for controlling the switching state (on/off) of three control switches 504, 506, and 508 that open or close access of the given access point P1, P2, P3 shown in FIG. 2 to the analog test bus 512. The combination of switching states shown in FIG. 5 shown in FIG. 5 is purely for illustrative purposes. By selectively controlling the switching states of the control switches 504, 506, and 508, using the control data entries in the test switching control register 502, the routing and reception of analog test signals to the given processing slice and of analog test response signals back to the configuration control unit 130 and configuration processor 128 can be handled effectively.

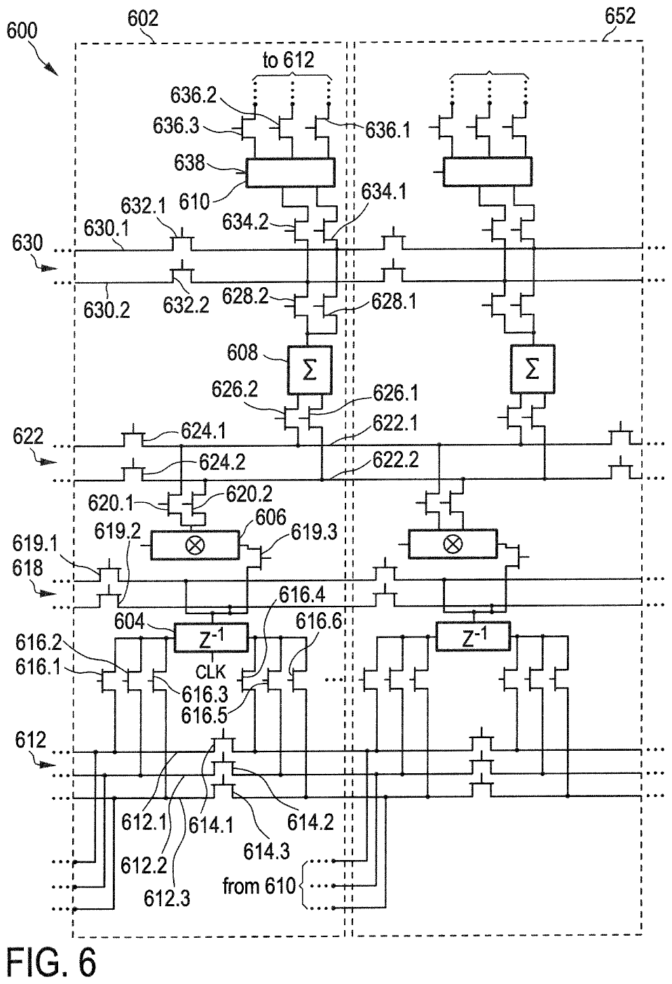

FIG. 6 is a simplified circuit diagram of a section of an analog processing array 600 with two mutually interconnected processing slices 602 and 652. The processing slices 602 and 652 are of identical structure. For that reason, only the processing slice 602 will be described in the following. The processing slice 602 comprises a configurable delay element 604, an analog multiplier element 606, an analog adder element 608 and an analog resample element 610. An in-out bus 612 of an analog signal bus comprises three in-out bus lines 612.1, 612.2 and 612.3 which are segmented and controllably used under the control of a first set of routing switches 614.1, 614.2, and 614.3, which in the present embodiment are FET switches controlled via their respective gate electrode. Access from the in-out bus lines to the delay element 604 for delivering an analog slice input signal and for receiving a delayed slice input signal back at the in-out bus is controlled by a second set of routing switches 616.1 to 616.6. The controllable delay element 604 also receives a clock signal via a clock input port CLK.

A multiplier bus 618 of the analog signal bus connects the output of the controllable delay element 604 with the analog multiplier element 606 of the local processing slice and with the analog multiplier elements of other processing slices downstream in the signal flow for providing the delayed slice input signal to the multiplier element 606 of the processing slice 602 or to any of the multiplier elements of other processing slices downstream in the processing flow. The routing along the multiplier bus is controlled by routing switches 619.1 to 619.3.

The multiplier output signal from the analog multiplier element 606 is controllably fed via routing switches 620.1 and 620.2 to an adder bus 622 of the analog signal bus. In this exemplary embodiment, the adder bus 622 comprises two adder bus lines 622.1 and 622.2, each of which can be selected for carrying the multiplier output signal via an on-off control of the routing switches 620.1 and 620.2. It is noted here that the number of bus lines of the analog signal bus components can be selected according to the discretion of the designer of the PASPA.

Routing along the shown segment of the adder bus 622 and to the inputs of the analog adder element 608 is controlled via a third set of routing switches 624.1, 624.2 and a fourth set of routing switches 626.1 and 626.2, respectively. The adder output signal is fed via a fifth set of routing switches 628.1 and 628.2 to signal lines 630.1 and 630.2 of a resampler bus 630. A sixth set of routing switches 632.1 and 632.2 controls the routing of the analog adder output signals along the resampler bus 630. The analog adder output signal is received by the analog resample element 610 via a seventh set of routing switches, which feeds its slice output signal to the in-out bus 612 via an eighth set of routing switches 636.1 to 636.3 with a suitable cell-output delay. The function of the analog resample element is thus to provide a track-and-hold function. This serves in particular for stabilizing the slice output signal. The cell-output delay is configurable via a resample configuration input 638 of the resample element 610 using control signals provided by the configuration control unit. In other embodiments, an additional local control element (not shown) or macrocell-internal control element as discussed in the context of FIG. 3 (control element 308) may be used for setting and, if necessary, adapting the cell-output delay.

It is noted that throughout the exemplary drawings, the routing switches are shown as single transistors, in particular FETs. However, instead of transistors, other suitable switching elements can be used any of the embodiments disclosed herein. For instance, CMOS-based transmission gates or MEMS switches are suitable alternatives for use as a routing switch. Thus, by suitable control of the routing switches using the control element 308, each processing slice can be programmed to perform a desired signal processing function from a large variety of analog signal processing functions. A particularly simple example is the use as a controllable delay element, as explained in the context of FIG. 3. The further processing and routing options provide combination options of multiplication and summation functions, which in connection with the operation of other processing slices in the programmed signal flow allow implementing a wide range of analog signal processing schemes.

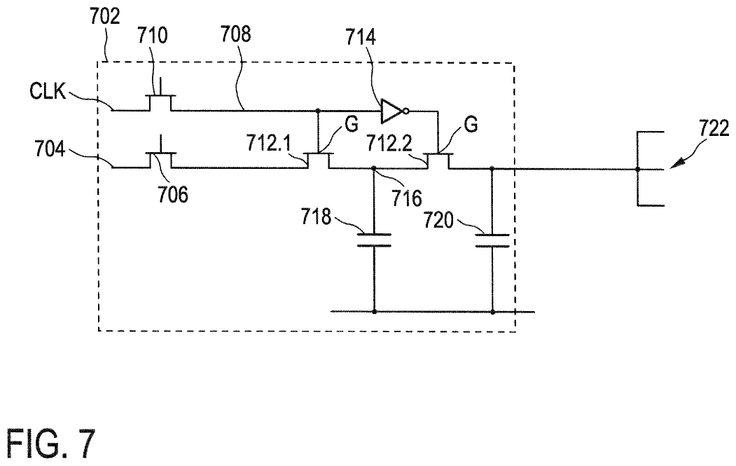

FIG. 7 is a simplified circuit diagram of a delay element 702 suitable for use in a processing slice of a programmable signal processing array of the present invention. A slice input signal is received via an in-out bus 704 (shown by a single bus line for simplicity) and passes a signal routing switch 706. A single two-phase clock signal is received at a clock input CLK and fed to a clock line 708via a clock routing switch 710. The delay element 702 comprises a series of two (or more) delay control switches 712.1 and 712.2. Each of the delay control switches 712.1 and 712.2 has a control gate G for controlling opening and closing of the respective switch in accordance with the two phases of two non-overlapping clock signal trains received at the respective control gate. In the present example, the delay element 702 receives the single two-phase clock signal train and generates a second, non-overlapping clock signal train by means of an inverter 714 that is arranged downstream of a branch point 716 connecting the control gate G of the first delay control switching element 712.1 with the clock line 708. The second clock signal train is thus generated as a phase-inverted version of the first clock signal train.

The slice input signal received via the in-out bus 704 is fed through the gate-controlled channel of the delay control switches 712.1 and 712.2 and feeds a parallel connection of two capacitors 718 and 720 connected to a reference voltage (e.g., mass), wherein a respective one of the capacitors 718, 722 is arranged downstream of each delay control switch 712.1., 712.2.

In operation, the received slice input signal is forwarded stepwise by means of the control action of the two-phase non-overlapping clock signals, and experiences a delay in terms zero or one clock period, or multiples of the clock signal period, depending on the controlled feeding of the clock signal via the clock routing switch 710. Thus, the delayed slice input signal is provided behind the last switching element in the direction of signal flow to the multiplier bus 722 via respective routing switches (not shown). The delay element thus corresponds to a series connection of two analog latches enables a time-discrete analog signal processing scheme.

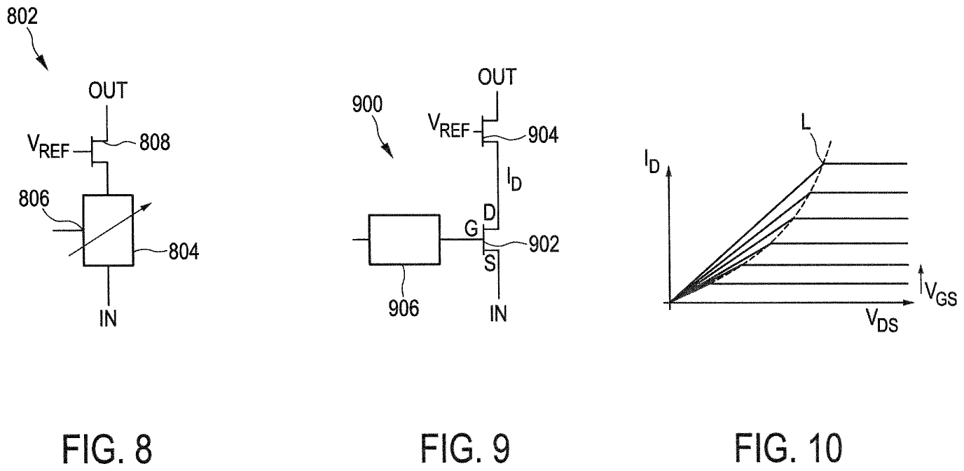

FIG. 8 is a schematic diagram of an analog multiplier element for use in a processing slice. The analog multiplier element 804 receives the delayed slice input signal as a voltage signal at a multiplier input IN. The delayed slice input signal is provided, e.g., by the delay element 702 of FIG. 7. A memristor 804 forms a controllable ohmic resistive element and performs an analog multiplication with a programmable multiplication factor. A control input 806 serves for receiving the multiplication factor from the configuration control unit (cf. FIG. 1, FIG. 3). A transistor 808 serves for providing a reference voltage V_{REF} to a reference input. A voltage V_{REF}−V_{GS} is then provided to the memristor 804, where V_{GS} is the gate-source voltage drop of the transistor 808.

A voltage difference between the voltage V_{REF}−V_{GS} and the multiplier input voltage formed by the delayed slice input signal at the multiplier input IN results in an output current provided at a multiplier output OUT. The output current is proportional to a product of the multiplier input voltage and of the preconfigured multiplication factor of the memristor 804. Thus, the current signal generated by the analog multiplier 802 corresponds to the desired analog product and shows an excellent linearity.

FIGS. 9 shows an alternative implementation of an analog multiplier element 900 that comprises a field effect transistor (FET) 902 and a reference transistor 904 for providing a reference voltage V_{REF}. A control gate G of the FET 902 is fed by a digital-analog converter (DAC) 906 that provides the multiplication factor via a digitally programmable, analog control voltage to the control gate G. The control voltage thus depends on the programmed multiplication factor. The control voltage determines a gate-to-source voltage V_{GS} applied to the FET 902, which in turn determines a channel resistance of the FET 902 and thus controls the drain current ID flowing from a drain electrode D through the channel of the FET and the source electrode due to the voltage difference between the multiplier input voltage and the voltage V_{REF}−V_{GS′}, wherein V_{GS′} is the gate-source voltage drop at the reference transistor 904. In operation of the analog multiplier element 900, a multiplier input voltage is applied to the FET 902 via its source electrode 902. An output current at the multiplier output OUT is provided by the drain current ID, which is in correspondence with a product of the multiplier input voltage at the multiplier input IN and the multiplication factor. The multiplier output signal is thus provided in the form of a current signal.

Additional reference is now made to FIG. 10, which is a diagram showing the drain current I_{D} vs. the drain-to-source voltage V_{DS} for several values of V_{GS}. For an operation as an analog multiplier, the FET is operated in a linear range to the left (i.e. lower V_{DS}) of the dotted line L. With a given multiplier input voltage applied to the drain D of the FET 902, a drain current I_{D} will be output that depends on the control voltage applied to the gate electrode G, i.e., on the gate-to-source voltage V_{GS}. As can be seen from FIG. 10, increasing V_{DS} in the linear range of the FET at a fixed V_{GS}, i.e., multiplication factor, will result in a linear increase of the drain current I_{D}. The drain current thus is proportional to a product of the drain-to-source voltage, i.e., multiplier input voltage, with a multiplication factor that is determined by the gate-to-source voltage V_{GS}. Furthermore, if the multiplication factor is to be set (programmed) to a higher value for a given multiplier input voltage (V_{DS}), the gate-to-source voltage V_{GS} can be set to a higher value via DAC 906. This will result in a steeper linear increase of the drain current I_{D} as a function of the drain-to-source voltage V_{DS}, which thus corresponds to the desired increased multiplication factor. Prestored data of the characteristic diagram of the FET 902 as visualized by FIG. 10 thus forms the basis for proper programming of the multiplication factor of the analog multiplier 900 by the configuration control unit 130.

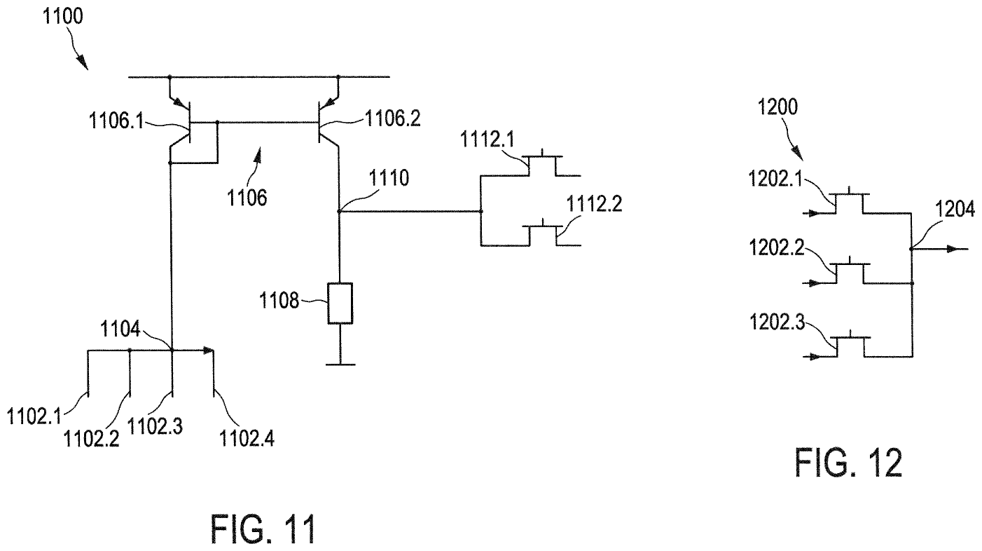

FIG. 11 shows a circuit diagram of an exemplary analog adder element 1100 suitable for use in a processing slice. Four adder input ports 1102.1 to 1102.4 receiving respective adder input signals in the form of current signals. The number of four adder input signals is selected as an example only. Other numbers of input signals can be used at the discretion of the circuit designer in accordance with the requirements of a given application case. The received input current signals are merged and thus added at a node 1104. The resulting current sum is fed into a current mirror 1106 formed of two pnp transistors 1106.1 and 1106.2, which are connected to a power supply (not shown) supplying a constant dc operating voltage. The mirrored current provided by a collector of transistor 1106.2 is subjected to current-voltage conversion using a resistor 1108, and an output voltage is provided as a common-mode voltage level at an output node 1110 for feeding to the resampler bus (not shown) and into a subsequent resampler element (not shown) via routing switches 1112.1 and 1112.2.

The adder element 1100 thus receives current input signals via the adder input ports 1102.1 to 1102.4 and provides an adder output signal in the form of an output voltage that has an amount, which is derived from and indicative of the sum of the received input current amounts.

FIG. 12 shows a circuit diagram of another exemplary adder element 1200 suitable for use in a processing slice. The present embodiment serves for adding two adder input signals that are provided in the form of current signals. Three adder input ports 1202.1 to 1202.3 serve for receiving respective adder input signals in the form of electrical current amounts. Again, the number of input ports is of exemplary nature and may be varied by the circuit designer. In the present embodiment, the adder input ports comprise routing switches, which allow a programmable selection of a number of input ports to be used in a given application case. It is noted that this form of programmable selection of adder input ports can also be used in the embodiment of FIG. 11. The input signals are fed together at a nodal point 1204, so that the input current amounts of the selected input signals add up and a sum of the input current amounts is provided as the adder output signal. In contrast to the embodiment of FIG. 11, the adder element 1200 thus keeps the analog signal in the current plane.

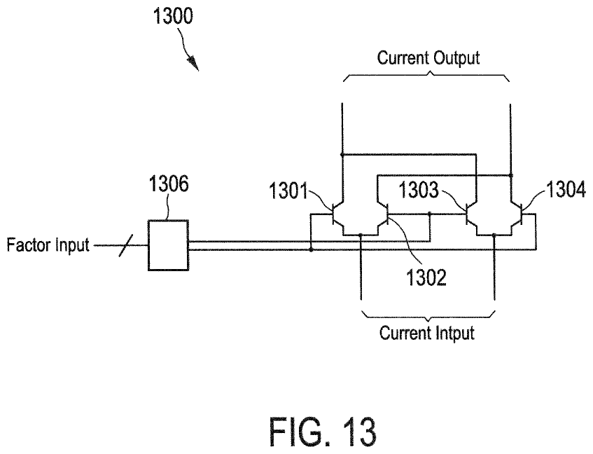

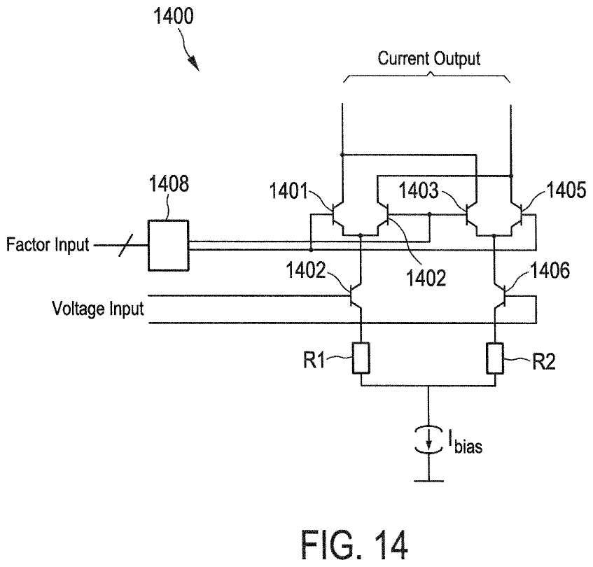

FIGS. 13 and 14 show circuit diagrams of further exemplary analog multiplier elements 1300 and 1400, respectively.

The analog multiplier element 1300 is a four-quadrant multiplier circuit that comprises two cross-coupled, emitter-coupled transistor pairs 1301, 1302 and 1303, 1304. It receives an input signal in the form of a delayed slice input current signal, and a digital factor input that is converted to an analog multiplication factor control voltage by a DAC 1306. The multiplier element 1300 provides a current output signal at connected outputs with opposite phase and of a current amount that corresponds to the product of the input current amount with the multiplication factor programmed via the DAC 1306.

The analog multiplier element 1400 is a four-quadrant circuit in the form a Gilbert multiplier cell. It comprises two cross-coupled, emitter-coupled transistor pairs 1501, 1504 and 1503, 1505 in series connection with an emitter-coupled transistor pair 1502, 1506, which feeds the cross-coupled pairs via the collectors of its transistors. The emitter-coupled transistor pair 1502, 1506 is fed by a bias current I_{bias} via two resistors R1, R2 of equal resistance. In contrast to the multiplier element 1300, the analog multiplier element 1400 receives the delayed slice input signal not as a current signal but as an voltage signal. As in the circuit of FIG. 13, the multiplication factor is provided in digital form and converted to an analog voltage signal by a DAC 1408. The multiplication factor is provided to respective base contacts of the emitter-coupled transistor pairs 1501, 1504 and 1503, 1505. The multiplier element 1400 provides a current output of a current amount that corresponds to the product of the input voltage amount with the factor.

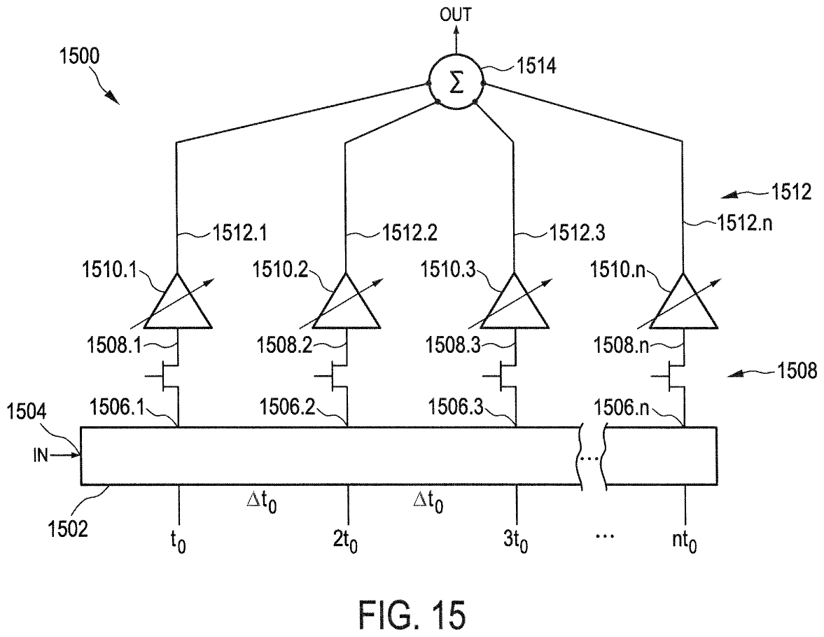

FIG. 15 is a schematic illustration of another embodiment of a processing slice 1500 for use in another embodiment of a PASPA. A true-time delay line 1502 received an analog input signal via an input port 1504. The input signal travels along the true-time delay 1502 line with a known propagation speed (in the current example, from left to right). As it travels along the true-time delay line 1502, the slice input signal experiences a continuously increasing delay due to its finite propagation speed. The delay element 1500 comprises a plurality of delay outputs ports 1506.1, 1506.2, 1506.3, . . . , 1506.n, which in the present example are arranged with equal spatial distance from their respective next neighboring output ports. This way, each of the delay output ports allows retrieving a respective delay output signal exhibiting a stepwise increase Δt₀ of the delay exhibited by the respective slice output signal in comparison with its next preceding delay output port. A desired delay output signal can be selected for forwarding to a respective bus line 1508.1, 1508.2, 1508.3, . . . , 1508.n of a multiplier bus 1508 using a set of routing switches 1506.1, 1506.2, 1506.3, . . . , 1506.n. Thus, by selecting a specific delay output port for providing its respective output signal as the delayed slice input signal, a control of the time delay exhibited by the delayed slice input signal is achieved. A maximum delay amount is achieved by retrieving the output signal at the output 1508.n of the true-time delay line. The number n of output ports can be selected according to the discretion of the designer.

Each of the bus lines 1508.1, 1508.2, 1508.3, . . . , 1508.n of the multiplier bus 1508 provides an input signal to an associated analog multiplier element 1510.1, 1510.2, 1510.3, . . . , 1510.n, which in the present case are provided in the form of respective variable gain amplifiers that receive their respective multiplication factor via respective control input ports.

The multiplier output signals are fed to respective bus lines 1512.1, 1512.2, 1512.3., . . . , 1512.n of an adder bus 1512 to form respective adder input signals of an analog adder 1514, which provides an adder output signal for instance in the form of a current signal to a resample bus (not shown) for feeding to a resampler (also not shown).

The processing slice 1500 is particularly advantageous for analog signal processing of very-high-frequency analog signals.

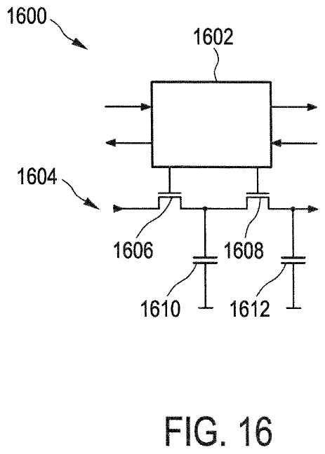

FIG. 16 is an illustration of a further implementation of a controllable delay element 1600 that uses a handshake concept in the signal communication between processing slices, as an alternative to the provision of a central clock signal for driving the controllable delay elements. The key concept of this implementation is a local delay control using a handshake circuit 1602 that controls a delay element 1604. The handshake circuit 1602 is associated with a processing slice or a macrocell of processing slices (not shown in FIG. 16) and controls the signal flow to and from other processing slices or macrocells.

In this embodiment, the analog signal bus is associated with and controlled by at least one hand-shake line for transporting communication control signals between the processing slices in accordance with a handshake protocol. The handshake circuit 1602 is configured to
generate and provide communication control signals on behalf of the respective associated processing slice or macro cell for asynchronous communication with other processing slices or macro cells of the network of processing slices or macro cells in accordance with a handshake protocol;
control the time delay in providing the delayed slice input signal by the delay element, and to
control a timing of an output of the multiplier output signal, or of the adder out-put signal via the signal bus in response to a protocol exchange with at least one target processing slice in accordance with the handshake protocol.

The communication control signals exchanged between handshake circuits of the processing slices or macrocells include requests for data transmissions and acknowledgement signals for acknowledging received requests.

The delay element circuit 1604 is similar to the delay element 702 shown in FIG. 7, except for not providing for an inversion of a received clock signal. Instead, it only comprises a series connection of two analog latches, wherein each analog latch comprises a respective delay control switch 1606, 1608, and a respective capacitor 1610, 1612. The on-off control of the delay control switches is performed by the handshake circuit 1602, which thus controls the delay effected by the delay element 1600.

The operation of the entire programmable analog signal processing array with asynchronous handshake signals, e.g. 4-phase handshake, and without any clock avoids or reduces unwanted influences of the clock signal on analog signal values due to, e.g., capacitive couplings or dips of an operating voltage.

In summary, a programmable analog processing array for programmable time-discrete processing of analog input signals in accordance with a desired signal processing function comprises a network of mutually interconnectable and pre-configurable analog processing slices that form unit circuit cells of the network. Each processing slice comprises a set of cell circuit elements including: a switchable clock input port for receiving a clock signal, a delay element for receiving a respective analog slice input signal and for forwarding the received slice input signal with a pre-configurable time delay as a respective delayed slice input signal, an analog multiplier element receiving the delayed slice input signal for providing an analog multiplier output signal corresponding to a product of the delayed slice input signal with a pre-configurable multiplication factor, an analog adder element receiving a pre-configurable selection of at least two adder input signals including the multiplier output signal and for providing an analog adder output signal corresponding to a sum of the adder input signals, and including an analog resample element for receiving the adder output signal and for providing the received adder output with a pre-configurable time delay as an analog slice output signal.

What is claimed is:

1. A programmable analog processing array for programmable time-discrete processing of incoming analog input signals in accordance with a desired signal processing function and for providing processed analog output signals in accordance with the signal processing function, the processing array comprising:
a network of mutually interconnectable and pre-configurable analog processing slices that form unit circuit cells of the network and that each comprise a set of cell circuit elements formed by
a switchable clock input port for receiving a clock signal;
a delay element for receiving a respective analog slice input signal and for forwarding the received slice input signal with a pre-configurable time delay as a respective delayed slice input signal;
an analog multiplier element receiving the delayed slice input signal, for providing an analog multiplier output signal corresponding to a product of the delayed slice input signal with a pre-configurable multiplication factor, and
an analog adder element receiving a pre-configurable selection of at least two adder input signals including the multiplier output signal, for providing an analog adder output signal corresponding to a sum of the adder input signals; and
an analog resample element for receiving the adder output signal and for providing the received adder output with a pre-configurable time delay as an analog slice output signal;
a pre-configurable analog signal bus for receiving and providing the analog input signals to the network of processing slices and for interconnecting any given processing slice to one or more respective other of the processing slices of the network of processing slices to transport the slice input signals and slice output signals;
a configuration-signal bus for receiving and routing respective configuration control signals to the individual processing slices, wherein the respective configuration control signals are for configuring
individual time delays of the respective delay elements,
individual multiplication factors of the respective multiplier elements,
individual selections of adder input signals to the respective adder elements,
individual switchable interconnections of the respective processing slices to the analog signal bus for routing, in accordance with a programmable signal-bus configuration and with the signal processing function, the input signals, the respective slice input signals, and the respective slice output signals between the processing slices via the analog signal bus;
and, connected to the network of processing slices,
individual switching states of the clock input ports for allowing or blocking the provision of the clock signal to the respective processing slices;
a configuration control unit for receiving a configuration code and for using the configuration code to generate the configuration control signals to configure the network of processing slices for implementing an analog signal processing circuit that in operation performs the desired signal processing function.

2. The programmable analog signal processing array of claim 1, wherein
the delay element is configured to receive the respective analog slice input signal as a first analog voltage signal and to provide the respective delayed slice input signal as a second analog voltage signal,
the analog multiplier element is configured to provide the analog multiplier output signal as a first analog current signal, and
the analog adder element is configured to receive the at least two adder input signals as analog current signals and to provide the analog adder output signal also as an analog current signal of an amount indicative of the sum of the adder input signals, and wherein
the resampling element comprises a current-to-voltage converter for receiving the analog adder output signal and for providing as the slice output signal an adder output voltage signal of an output voltage amount indicative of the current amount of the analog adder output signal; and wherein
a voltage plane of the slice output voltage signal of the current-to-voltage converter is the same as that of the slice input signal received by the delay element.

3. The programmable analog signal processing array of claim 2, further comprising
a configuration input port for receiving hardware description data defining, using a hardware description language, a structure and behavior of an analog signal processing circuit performing a signal processing function and to be implemented by the programmable analog signal processing array;
a configuration processor for transforming the hardware description data into net list data indicative of a net list of processing slices and for transforming the net list data into place-and-route data indicative of place-and-route information to be implemented using the network of processing slices and determining desired interconnections of the processing slices that implement the analog signal processing circuit, and for transforming the net list and the place-and-route data into the configuration code.

4. The programmable analog signal processing array of claim 1, wherein
the configuration processor is further configured to generate, using the hardware description data, desired slice response data that is indicative of individual desired delayed slice input signals of the respective cell circuit elements of the individual processing slices in response to one or more predetermined analog configuration test signals;
the programmable analog signal processing array further comprises an analog test bus, which is connected with the configuration control unit and which is connectable with the individual processing slices to provide them with the one or more analog configuration test signals generated by the configuration control unit and to provide the configuration control unit with respective individual slice test-response signals provided by the respective cell circuit elements of the processing slices, each in response to the one or more configuration test signals; wherein
the configuration control unit is configured to generate the one or more predetermined configuration test signals and to determine deviations of the received slice test-response signals from the desired slice response data in accordance with predetermined deviation criteria, and in case of determining a deviation for a given processing slice, to generate the adapted configuration data for the respective processing slice and use the adapted configuration data for providing one or more adapted configuration signals to the respective processing slice.

5. The programmable analog processing array of claim 1, further comprising a configuration memory for storing the net list, the place-and-route data, the configuration code, the configuration data and the adapted configuration data.

6. The programmable analog signal processing array of claim 1, wherein the multiplier element of the processing slices comprises a configurable memristor, which receives the delayed slice input signal and which is configured to provide the multiplier output signal as a current signal of a current amount that is indicative of a product of an input voltage amount of the delayed slice input signal multiplied by the multiplication factor.

7. The programmable analog signal processing array of claim 6, wherein the configuration control unit is configured
to use the configuration input data or, if present, the adapted configuration data to determine respective memristor configuration signal amounts to be applied to the respective memristor of the multiplier elements of the individual processing slices to set a respective multiplication weight factor of the respective multiplier element, and
to subject the respective memristor of the multiplier elements to the determined configuration signal of the determined configuration signal amount.

8. The programmable analog processing array of claim 4, wherein the configuration control unit is configured
to switch to an intermittent background calibration mode under operation of the processing array, and, in the background calibration mode,
to generate and provide via the analog test bus one or more multiplier test signals to the multiplier elements,
to determine from the received multiplier output signals a deviation of a respective multiplication factors from the respective desired multiplication factors according to the configuration code; and, in case of a determining a deviation,
to generate and provide a respective memristor re-configuration signal amount to be applied to the respective memristor of the multiplier elements of the individual processing slices in order to re-set the respective multiplication factor of the respective multiplier element to the desired value; and
to subject the respective memristor of the multiplier elements to the determined respective reconfiguration signal amount.

9. The programmable analog signal processing array of claim 1, wherein the analog signal bus comprises
a first signal bus, hereinafter analog in-out bus, for receiving the slice input signals and routing them to a pre-configurable set of processing slices and for receiving the slice output signals of the processing slices in accordance with the signal-bus configuration;
a second signal bus, hereinafter multiplier bus, for receiving the respective delayed slice input signals and routing them to a pre-configurable set of processing slices in accordance with the signal-bus configuration;
a third signal bus, hereinafter adder bus, for receiving the respective multiplier output signals and routing them to a controllable set of processing slices in accordance with the signal-bus configuration;
a fourth signal bus, hereinafter adder output bus, for receiving the respective adder output signals and routing them to a pre-configurable set of resample elements in accordance with the signal-bus configuration and to an output of the processing array,
wherein the analog in-out bus, the multiplier bus, the adder bus and the adder output bus are each switchably interconnectable with each of the processing slices in accordance with the signal-bus configuration.

10. The programmable analog signal processing array of claim 5, wherein
the network of processing slices is divided into identical macrocells that each comprise a plurality of processing slices,
the configuration control unit is configured to use the configuration code for generating respective configuration signals that establish desired electrical connections between the processing slices of a given macrocell;
each of the macrocells has an associated control element that receives the configuration signals associated with the processing slices of the given macrocell from the configuration control unit (130) for controlling a routing of
the configuration signals to the respective processing slices of the given macrocell,
the configuration test signals associated with the processing slices of the given macrocell and the slice test-response signals in response to the configuration test signals from the processing slices of the given macrocell via the analog test bus,
the clock signal to the respective processing slices of the given macrocell; and of
analog data signals between the processing elements of the processing slices via the analog signal bus.

11. The programmable analog signal processing array of claim 1, further comprising a clock generation unit configured to provide a pair of two-phase non-overlapping clock signal trains to the processing slices via the clock bus.

12. The programmable analog signal processing array of claim 1, wherein
the delay element of the processing slices comprises a series of at least two switching elements that receives the slice input signal, each of the switching elements also having a control gate receiving a respective one of the clock signal trains for opening and closing the switching element in accordance with the two phases of the respective clock signal train, and wherein the delay element further comprises parallel capacitances respectively arranged behind, in a direction of signal flow, each switching element, for providing the delayed slice input signal behind the last switching element in the direction of signal flow.

13. The programmable analog signal processing array of claim 1, wherein
the analog signal bus is associated with and controlled by at least one handshake line for transporting communication control signals between the processing slices in accordance with a handshake protocol;
the processing slices or, if present, macro cells each further comprise an associated handshake circuit which is configured to
generate and provide communication control signals on behalf of the respective associated processing slice or macro cell for asynchronous communication with other processing slices or macro cells of the network of processing slices or macro cells in accordance with a handshake protocol;
control the time delay in providing the delayed slice input signal by the delay element, and to
control a timing of an output of the multiplier output signal, or of the adder output signal via the signal bus in response to a protocol exchange with at least one target processing slice in accordance with the handshake protocol.

14. The programmable analog signal processing array of claim 3, wherein
the configuration processor is further configured to generate, using the hardware description data, desired slice response data that is indicative of individual desired delayed slice input signals of the respective cell circuit elements of the individual processing slices in response to one or more predetermined analog configuration test signals;
the programmable analog signal processing array further comprises an analog test bus, which is connected with the configuration control unit and which is connectable with the individual processing slices to provide them with the one or more analog configuration test signals generated by the configuration control unit and to provide the configuration control unit with respective individual slice test-response signals provided by the respective cell circuit elements of the processing slices, each in response to the one or more configuration test signals; wherein
the configuration control unit is configured to generate the one or more predetermined configuration test signals and to determine deviations of the received slice test-response signals from the desired slice response data in accordance with predetermined deviation criteria, and in case of determining a deviation for a given processing slice, to generate the adapted configuration data for the respective processing slice and use the adapted configuration data for providing one or more adapted configuration signals to the respective processing slice.

15. The programmable analog processing array of claim 4, further comprising a configuration memory for storing the net list, the place-and-route data, the configuration code, the configuration data and the adapted configuration data.

16. The programmable analog signal processing array of claim 5, wherein the multiplier element of the processing slices comprises a configurable memristor, which receives the delayed slice input signal and which is configured to provide the multiplier output signal as a current signal of a current amount that is indicative of a product of an input voltage amount of the delayed slice input signal multiplied by the multiplication factor.

17. The programmable analog processing array of claim 7, wherein the configuration control unit is configured
to switch to an intermittent background calibration mode under operation of the processing array, and, in the background calibration mode,
to generate and provide via the analog test bus one or more multiplier test signals to the multiplier elements,
to determine from the received multiplier output signals a deviation of a respective multiplication factors from the respective desired multiplication factors according to the configuration code; and, in case of a determining a deviation,
to generate and provide a respective memristor re-configuration signal amount to be applied to the respective memristor of the multiplier elements of the individual processing slices in order to re-set the respective multiplication factor of the respective multiplier element to the desired value; and
to subject the respective memristor of the multiplier elements to the determined respective reconfiguration signal amount.
